(19) United States
(12) Patent Application Publication
(10) Pub. No.: US 2015/0091087 A1
(43) Pub. Date: Apr. 2, 2015

(54) METAL OXIDE SEMICONDUCTOR (MOS) DEVICE AND MANUFACTURING METHOD THEREOF

(71) Applicant: Tsung-Yi Huang, Hsinchu (TW)

(72) Inventor: Tsung-Yi Huang, Hsinchu (TW)

(73) Assignee: RICHTEK TECHNOLOGY CORPORATION, Zhubei City (TW)

(21) Appl. No.: 14/456,734

(22) Filed: Aug. 11, 2014

(30) Foreign Application Priority Data
Sep. 30, 2013 (TW) 102135251

(51) Int. Cl. H01L 29/78; H01L 29/66; H01L 29/08; H01L 21/265

(52) U.S. Cl. CPC H01L 29/7833; H01L 21/265; H01L 29/66492; H01L 29/086; H01L 29/0878
USPC 257/336; 438/305

(57) ABSTRACT

The present invention discloses a metal oxide semiconductor (MOS) device and a manufacturing method thereof. The MOS device is formed in a substrate with an upper surface and it includes: an isolation region, a well region, a gate, a lightly-doped-source (LDS), a lightly-doped-drain (LDD), a source, and a drain. The isolation region defines an operation region. The gate includes: a dielectric layer, a stack layer, and a spacer layer, wherein the stack layer separates the operation region to a first side and a second side. The LDS with a first conductive type, is formed in the substrate beneath the upper surface, and at least part of the LDS overlaps the stack layer from a top view. The source with a second conductive type overlaps the spacer layer at the first side. The conductive types of the LDS and the source are different to mitigate the threshold voltage roll-off.

### CROSS REFERENCE

The present invention claims priority to TW 102135251, filed on Sep. 30, 2013.

### BACKGROUND OF THE INVENTION

1. Field of Invention

The present invention relates to a metal oxide semiconductor (MOS) device and a manufacturing method thereof; particularly, it relates to such MOS device and manufacturing method thereof including a lightly-doped-source with a conductive type opposite to a conductive type of a source for mitigating threshold voltage roll-off.

2. Description of Related Art

FIGS. 1A and 1B are schematic diagrams showing a cross-section view and a top view of a prior art metal oxide semiconductor (MOS) device 100 respectively. As shown in FIGS. 1A and 1B, the MOS device 100 is formed in a substrate 11 and includes: a well region 12, an isolation region 13, a gate 14, a lightly-doped-drain 15, a source 16, and a drain 17. The isolation region 13 defines an operation region 13a of the MOS device 100. The gate 14 includes a dielectric layer 14a, a stack layer 14b, and a spacer layer 14c. The well region 12 has an N-type conductivity, and the lightly-doped-drain 15, the source 16, and the drain 17 have a P-type conductivity. P-type impurities usually include boron atoms or boron-containing molecules. As shown in FIG. 1A, in the substrate 11, the P-type impurities of the lightly-doped-drain 15 diffuse underneath the stack layer 14b after a thermal process step. When the MOS device 100 operates, a threshold voltage roll-off may occur because of drain induced barrier lowering (DIBL), and therefore the characteristics of the MOS device 100 are unstable, and the performance of the MOS device 100 is decreased.

In view of above, to overcome the drawbacks in the prior art, the present invention proposes a MOS device and a manufacturing method thereof, which can mitigate DIBL and threshold voltage roll-off of the MOS device.

### SUMMARY OF THE INVENTION

From one perspective, the present invention provides a metal oxide semiconductor (MOS) device, formed in a substrate with an upper surface, including: an isolation region, which is formed on the upper surface for defining an operation region; a well region with a first conductive type, which is formed beneath the upper surface in the substrate; a gate, which is formed on the upper surface, wherein the gate is located in the operation region from top view, and the gate includes: a dielectric layer, which is formed on the upper surface and in contact with the upper surface; a stack layer, which is formed on the dielectric layer; and a spacer layer, which is formed outside side walls of the stack layer, wherein the stack layer divides the operation region into a first side and a second side; a lightly-doped-source (LDS) with the first conductive type, which is formed at the first side beneath the upper surface of the substrate, wherein at least part of the LDS overlaps the stack layer from a top view; a lightly-doped-drain (LDD) with a second conductive type, which is formed at the second side beneath the upper surface of the substrate; a source with the second conductive type, which is formed at the first side beneath the upper surface of the substrate, wherein part of the source overlaps the spacer layer at the first side from the top view; and a drain with the second conductive type, which is formed at the second side beneath the upper surface of the substrate.

From another perspective, the present invention provides a manufacturing method of a metal oxide semiconductor (MOS) device, including: providing a substrate, which has an upper surface; forming an isolation region on the upper surface to define an operation region; forming a well region with a first conductive type beneath the upper surface in the substrate; forming a dielectric layer on the upper surface and in contact with the upper surface; forming a stack layer on the dielectric layer, which divides the operation region into a first side and a second side; forming a lightly-doped-source (LDS) with the first conductive type beneath the upper surface at the first side in the substrate, wherein at least part of the LDS overlaps the stack layer from a top view; forming a lightly-doped-drain (LDD) with a second conductive type beneath the upper surface at the second side in the substrate; forming a spacer layer outside side walls of the stack layer; forming a source with the second conductive type beneath the upper surface at the first side in the substrate, wherein part of the source overlaps the spacer layer at the first side from the top view; and forming a drain with the second conductive type beneath the upper surface at the second side in the substrate.

In one preferable embodiment, one side of the source is aligned with one side of the stack layer, or part of the source overlaps the stack layer from the top view.

In one preferable embodiment, at least part of the lightly-doped-drain overlaps the spacer layer at the second side from the top view.

In one preferable embodiment, one side of the drain is aligned with one side of the spacer layer at the second side or aligned with one side of the stack layer, or part of the drain overlaps the stack layer from the top view.

In one another preferable embodiment, the source is formed by: a self-aligned ion implantation process step, which implants the second conductive impurities to the substrate masked by the stack layer or the gate in the form of accelerated ions; and a thermal process step, which anneals the source with a process temperature exceeding 650 degrees Celsius, such that the second conductive type impurities diffuse underneath the spacer layer relatively near the first side.

The objectives, technical details, features, and effects of the present invention will be better understood with regard to the detailed description of the embodiments below.

### BRIEF DESCRIPTION OF THE DRAWINGS

FIGS. 1A-1B show a cross-section view and a top view of a prior art MOS device 100 respectively.

FIGS. 2A-2B show a first embodiment of the present invention.

FIGS. 3, 4, and 5 show a second, third, and fourth embodiments of the present invention respectively.

FIG. 6 for example shows threshold voltage and conductive resistance characteristic curves of MOS devices of the prior art and the present invention.

FIGS. 7A-7J show a fifth embodiment of the present invention.

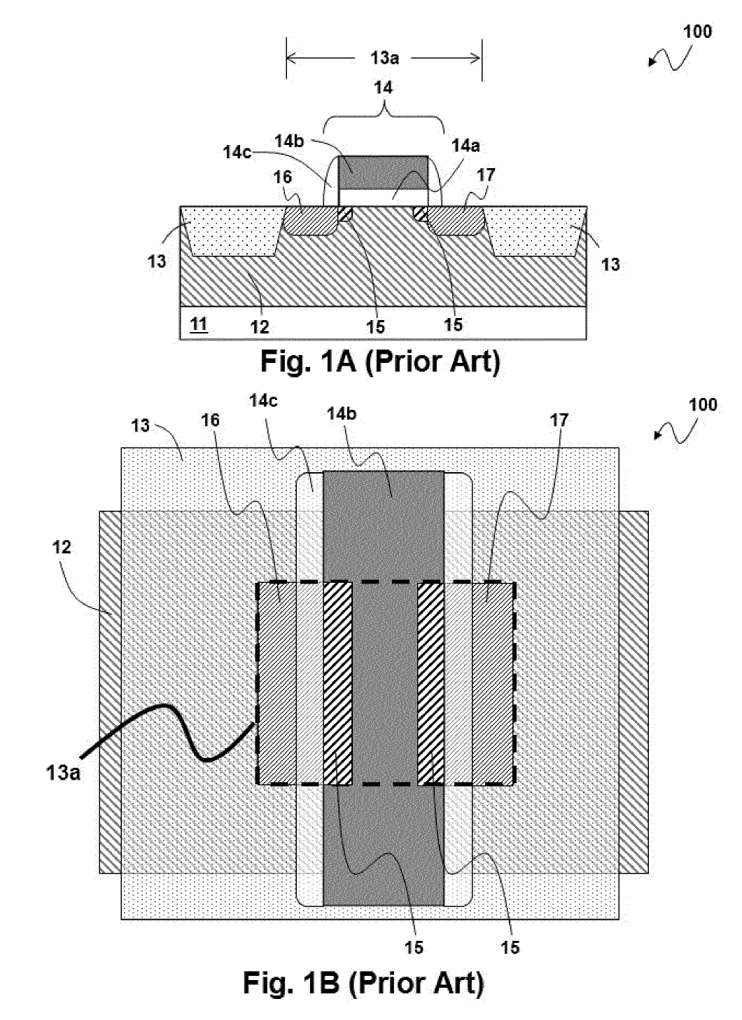

### DESCRIPTION OF THE PREFERRED EMBODIMENTS

The drawings as referred to throughout the description of the present invention are for illustration only, to show the interrelations between the regions and the process steps, but not drawn according to actual scale.

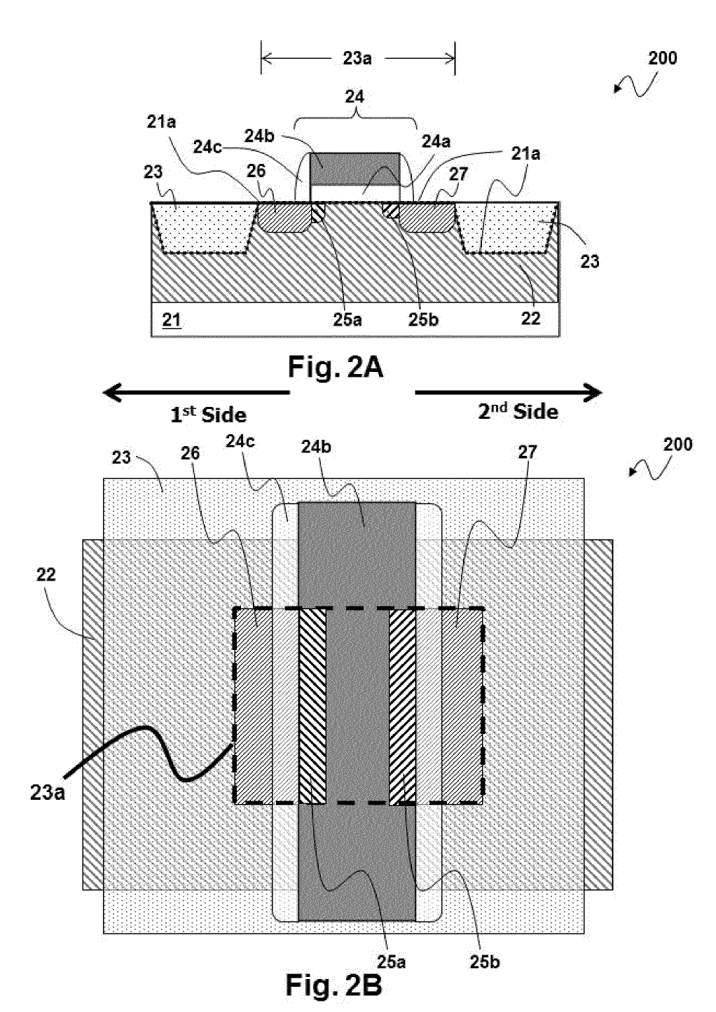

Please refer to FIGS. 2A and 2B fora first embodiment according to the present invention, wherein FIGS. 2A and 2B are schematic diagrams of a MOS device 200 from a cross-section and a top view respectively. As shown in FIGS. 2A and 2B, the MOS device 200 is formed in a substrate 21 with an upper surface 21a (as indicated by a dashed line shown in FIG. 2A). The MOS device 200 includes a well region 22, an isolation region 23, a gate 24, a lightly-doped-source (LDS) 25a, a lightly-doped-drain (LDD) 25b, a source 26, and a drain 27. The gate 24 includes a dielectric layer 24a, a stack layer 24b, and a spacer layer 24c. The substrate 21 is for example but not limited to a P-type silicon substrate, and the substrate 21 may be a semiconductor substrate other than the silicon substrate. The well region 22 is formed beneath the upper surface 21a. The isolation region 23 is formed on the upper surface 21a for defining an operation region 23a of the MOS device 200. The operation region 23a is located in the well region 22, which is indicated by a thick dashed frame as shown in FIG. 2B. The conductive type of the well region 22 and the LDS 25a is for example but not limited to the P-type (but they can be N-type in an MOS device of a different conductivity type). The conductive type of the LDD 25b, the source 26, and the drain 27 is for example but not limited to the N-type (but they can be P-type in the MOS device of the different conductivity type). The gate 24 is formed on the upper surface 21a between the source 26 and the drain 27. The stack layer 24b divides the operation region 23a into a first side and a second side as indicated by thick arrows shown in FIG. 2B. The dielectric layer 24a is formed on the upper surface 21a, in contact with the upper surface 21a. The stack layer 24b includes a conductive material, and it is formed on the dielectric layer 24a as an electrical contact of the gate 24. In one embodiment, the stack layer 24b may be used as a self-aligned mask for forming the LDS 25a and/or the LDD 25b. The spacer layer 24c includes an insulating material, and it is formed outside the side walls of the stack layer 24b, overlaying the side walls of the stack layer 24b. In one embodiment, the spacer layer 24c maybe used as a self-aligned mask for forming the source 26 and/or the drain 27. The LDS 25a is formed at the first side beneath the upper surface 21a of the substrate 21, and at least part of the LDS 25a overlaps the stack layer 24b from the top view of FIG. 2B. In this embodiment, for example, the LDS 25a is completely inside the stack layer 24b (with one side of the LDS 25a aligned with one side of the stack layer 24b) from the top view of FIG. 2B. The LDD 25b is formed at the second side beneath the upper surface 21a of the substrate 21. The source 26 is formed at the first side beneath the upper surface 21a of the substrate 21, and part of the source 26 overlaps the spacer layer 24c at the first side from the top view of FIG. 2B. The drain 27 is formed at the second side beneath the upper surface 21a of the substrate 21. In one embodiment, one side of the drain 27 is aligned with one side of the stack layer 24b (from the top view of FIG. 2B), or in another embodiment, part of the drain 27 may extend beneath the stack layer 24b.

This embodiment is different from the prior art in that, in this embodiment, the LDS 25a has a conductive type opposite to the conductive type of the source 26 to suppress the threshold voltage (Vth) roll-off because of DIBL. That is, with the same Vth as the prior art MOS device, the MOS device according to the present invention may have a relatively shorter channel, such that the device conductive resistance can be reduced, and the device operation speed can be increased.

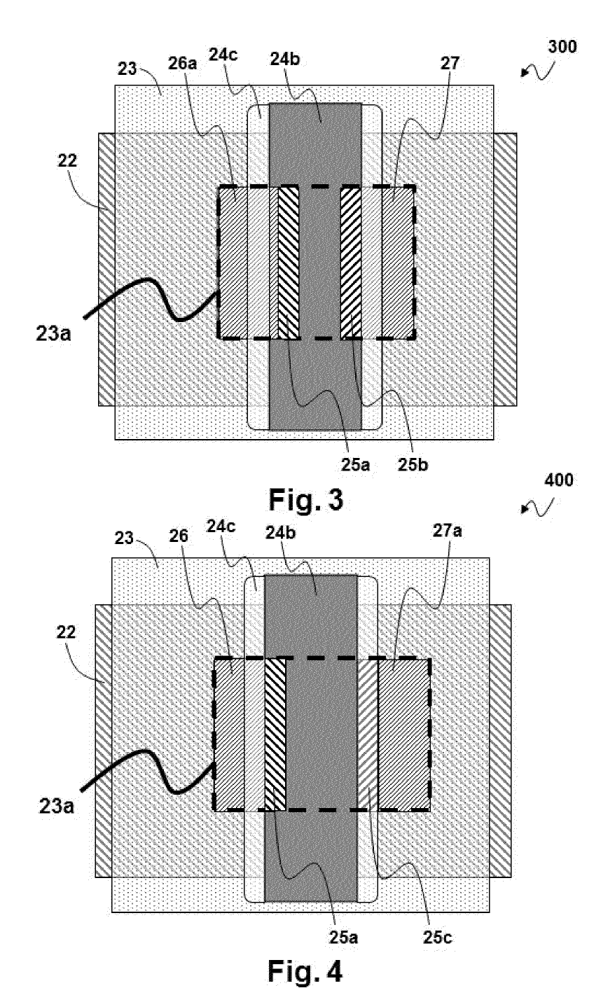

FIG. 3 shows a second embodiment of the present invention. FIG. 3 is a schematic diagram of a MOS device 300 from top view. This embodiment shows that part of the source 26a may overlap the stack layer 24b from the top view of FIG. 3 according to the present invention. (That is, part of the source 26a may extend beneath the stack layer 24b.)

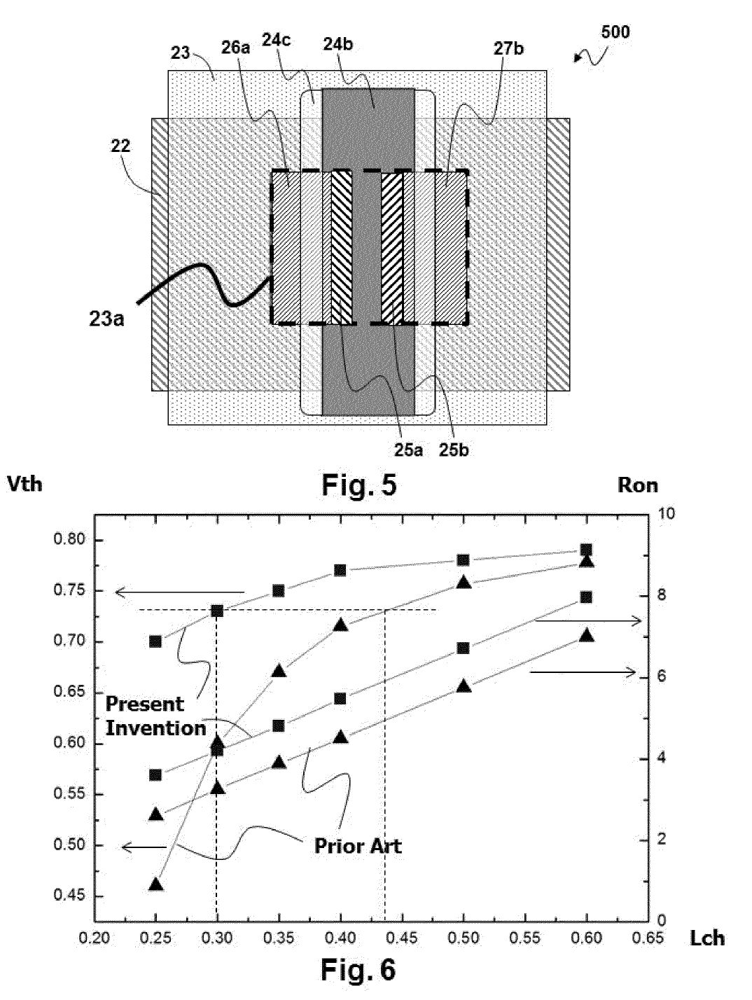

FIG. 4 shows a third embodiment of the present invention. FIG. 4 is a schematic diagram of a MOS device 400 from top view. This embodiment shows that the LDD 25c overlaps the spacer layer 24c at the second side, and two sides of the LDD 25c may be aligned with the two sides of the spacer layer 24c at the second side from the top view of FIG. 4; further, one side of the drain 27a is aligned with one side of the spacer layer 24c at the second side from the top view of FIG. 4.

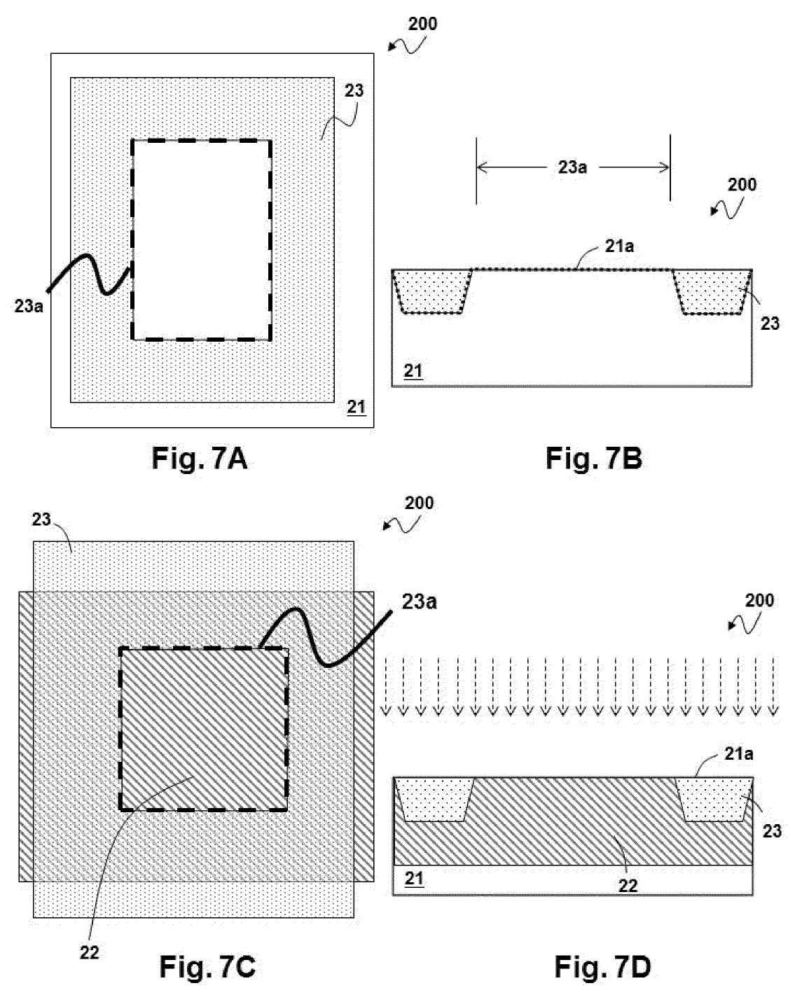

FIG. 5 shows a fourth embodiment of the present invention. FIG. 5 is a schematic diagram of a MOS device 500 from the top view. This embodiment shows that part of the source 26a and part of the drain 27b overlap the stack layer 24b from the top view of FIG. 5.

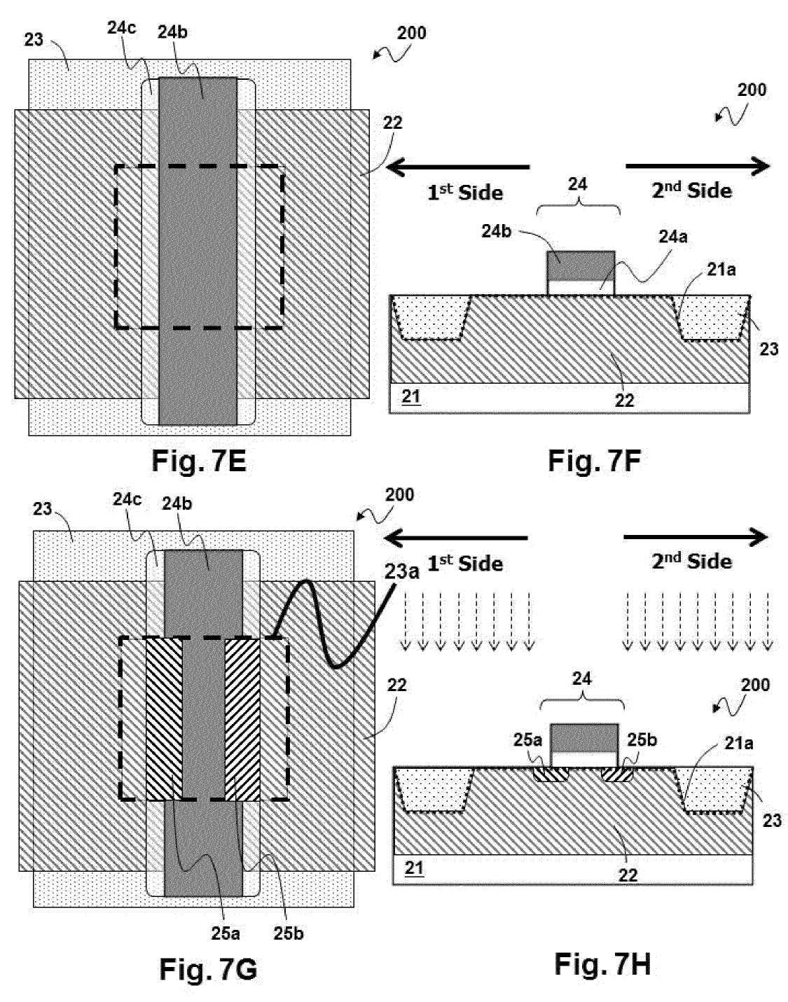

FIG. 6 shows characteristic curves of the threshold voltage (Vth) and the conductive resistance (Ron) versus a channel length (Lch) of the MOS devices according to the prior art and the present invention. Curves with triangular nodes are the characteristic curves of Vth and Ron according to the prior art; curves with square nodes are the characteristic curves of Vth and Ron according to the present invention. The characteristic curve of Vth according to the prior art shows an obvious threshold voltage roll-off when the channel length is decreased in the prior art MOS device. On the other hand, the threshold voltage roll-off is significantly mitigated in the MOS device according to the present invention. Referring to the characteristic curves of Ron, with the same Vth, the MOS device according to the present invention has a relatively shorter channel length and a relatively lower Ron as indicated by dashed lines shown in the figure. Therefore, with the same Vth, the MOS device according to the present invention has a relatively smaller size, and a relatively higher operation speed. These are advantages of the present invention over the prior art.

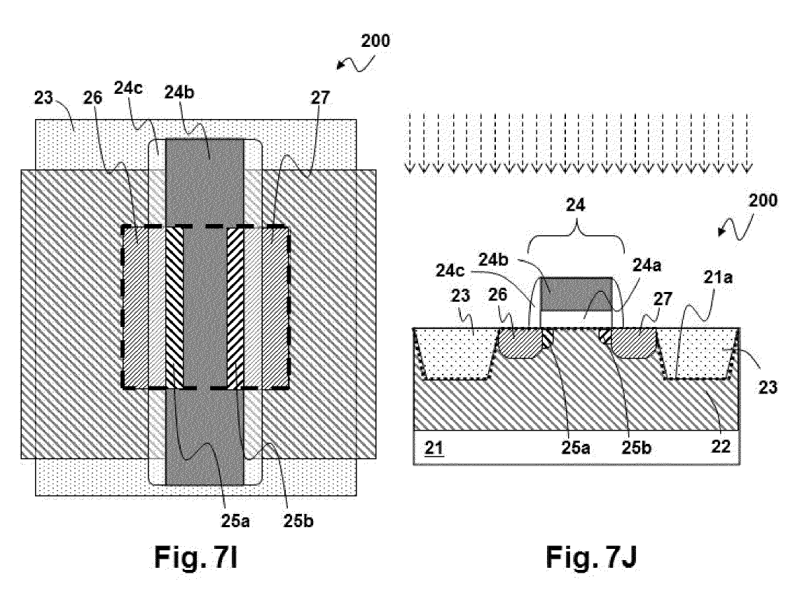

FIGS. 7A-7J show a fifth embodiment of the present invention. This embodiment shows an embodiment of a manufacturing method of the MOS device 200 in the first embodiment according to the present invention. For better understanding, top views and cross-section views of the MOS device 200 are shown at left and right sides in the drawing sheets. As shown in FIGS. 7A and 7B, a substrate 21 with an upper surface 21a (as shown by the dashed line in FIG. 7B) is provided, and an isolation region 23 is formed by for example but not limited to an oxidation process step. The isolation region 23 for example is a shallow trench isolation (STI) structure as shown in FIG. 7B, or a local oxidation of silicon (LOCOS) structure (not shown). The isolation region 23 is formed on the upper surface 21a for defining an operation region 23a as indicated in FIGS. 7A and 7B.

Next, as shown in FIGS. 7C and 7D, an N-type well region 22 is defined by for example but not limited to a photoresist mask formed by a lithography process step, and an ion implantation process step implants N-type impurities to the defined regions in the form of accelerated ions as indicated by the dashed arrow lines shown in FIG. 7D. The N-type well region 22 is formed beneath the upper surface 21a.

Next, as shown in FIGS. 7E and 7F, a dielectric layer 24a is formed on the upper surface 21a, in contact with the upper surface 21a. Next, a stack layer 24b is formed on the dielectric layer 24a, and the stack layer 24b divides the operation region 23a into the first side and the second side. Next, as shown in FIGS. 7G and 7H, LDS 25a and LDD 25b are defined by for example but not limited to a photoresist mask (not shown) formed by a lithography process step together with a self-aligned effect provided by the stack layer 24b, and ion implantation process steps are performed to implant N-type and P-type impurities to the defined regions at the first side and the second side respectively in the form of accelerated ions as indicated by the dashed arrow lines shown in FIG. 7H, to form the N-type LDS 25a and P-type LDD 25b beneath the upper surface 21a. At least part of the LDS 25a overlaps the stack layer 24b from the top view FIG. 7G.

Next, as shown in FIGS. 7I and 7J, a spacer layer 24c is formed outside the side walls of the stack layer 24b. Next, a source 26 and a drain 27 are defined by for example but not limited to a photoresist mask (not shown) formed by a lithography process step together with a self-aligned effect provided by the gate 24, and an ion implantation process step implants P-type impurities to the defined regions in the form of accelerated ions as indicated by the dashed arrow lines shown in FIG. 7J to form the P-type source 26 and P-type drain 27 beneath the upper surface 21a. The gate 24 is located between the source 26 and the drain 27. The source 26 and the drain 27 do not overlap each other. Part of the source 26 overlaps the spacer layer 24c at the first side from the top view FIG. 7I.

In one embodiment, the source 26 is formed by process steps for example including:

the aforementioned self-aligned ion implantation process step, which implants the P-type impurities to the substrate 21 masked by the stack layer 24b or the gate 24, in the form of accelerated ions; and
a thermal process step, which anneals the source 26 with a process temperature exceeding 650 degrees Celsius, such that the P-type impurities diffuse underneath the spacer layer 24c at the first side.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. For example, other process steps or structures which do not affect the primary characteristic of the device, such as a threshold voltage adjustment implant, etc., can be added; for another example, the lithography step described in the above can be replaced by electron beam lithography, X-ray lithography, etc.; for another example, in all the aforementioned embodiments, the P (or N) conductive type of an implanted region can be changed to the N (or P) type with corresponding modifications in other regions. In view of the foregoing, the spirit of the present invention should cover all such and other modifications and variations, which should be interpreted to fall within the scope of the following claims and their equivalents. An embodiment or a claim of the present invention does not need to achieve all the objectives or advantages of the present invention. The title and abstract are provided for assisting searches but not for limiting the scope of the present invention.

What is claimed is:

1. A metal oxide semiconductor (MOS) device, formed in a substrate with an upper surface, the MOS device comprising:
an isolation region, which is formed on the upper surface for defining an operation region;
a well region with a first conductive type, which is formed beneath the upper surface in the substrate;
a gate, which is formed on the upper surface, wherein the gate is located in the operation region from top view, and the gate includes:
a dielectric layer, which is formed on the upper surface and in contact with the upper surface;
a stack layer, which is formed on the dielectric layer; and
a spacer layer, which is formed outside side walls of the stack layer, wherein the stack layer divides the operation region into a first side and a second side;
a lightly-doped-source (LDS) with the first conductive type, which is formed at the first side beneath the upper surface of the substrate, wherein at least part of the LDS overlaps the stack layer from a top view;
a lightly-doped-drain (LDD) with a second conductive type, which is formed at the second side beneath the upper surface of the substrate;
a source with the second conductive type, which is formed at the first side beneath the upper surface of the substrate, wherein part of the source overlaps the spacer layer at the first side from the top view; and
a drain, with the second conductive type, which is formed at the second side beneath the upper surface of the substrate.

2. The MOS device of claim 1, wherein one side of the source is aligned with one side of the stack layer, or part of the source overlaps the stack layer from the top view.

3. The MOS device of claim 1, wherein at least part of the lightly-doped-drain overlaps the spacer layer at the second side from the top view.

4. The MOS device of claim 1, wherein one side of the drain is aligned with one side of the spacer layer at the second side or aligned with one side of the stack layer, or part of the drain overlaps the stack layer from the top view.

5. The MOS device of claim 1, wherein the source is formed by:
a self-aligned ion implantation process step, which implants the second conductive impurities to the substrate masked by the stack layer or the gate in the form of accelerated ions; and
a thermal process step, which anneals the source with a process temperature exceeding 650 degrees Celsius, such that the second conductive type impurities diffuse underneath the spacer layer relatively near the first side.

6. A manufacturing method of a metal oxide semiconductor (MOS) device, comprising:
providing a substrate, which has an upper surface;
forming an isolation region on the upper surface to define an operation region;
forming a well region with a first conductive type beneath the upper surface in the substrate;
forming a dielectric layer on the upper surface and in contact with the upper surface;
forming a stack layer on the dielectric layer, which divides the operation region into a first side and a second side;
forming a lightly-doped-source (LDS) with the first conductive type at the first side beneath the upper surface of the substrate, wherein at least part of the LDS overlaps the stack layer from a top view;
forming a lightly-doped-drain (LDD) with a second conductive type at the second side beneath the upper surface of the substrate;
forming a spacer layer outside side walls of the stack layer;
forming a source with the second conductive type at the first side beneath the upper surface of the substrate, wherein part of the source overlaps the spacer layer at the first side from the top view; and
forming a drain with the second conductive type at the second side beneath the upper surface of the substrate.

7. The manufacturing method of claim 6, wherein one side of the source is aligned with one side of the stack layer, or part of the source overlaps the stack layer from top view.

8. The manufacturing method of claim 6, wherein at least part of the lightly-doped-drain overlaps the spacer layer at the second side from the top view.

9. The manufacturing method of claim 6, wherein one side of the drain is aligned with one side of the spacer layer at the second side or aligned with one side of the stack layer, or part of the drain overlaps the stack layer from the top view.

10. The manufacturing method of claim 6, wherein the step of forming the source includes:
implanting the second conductive impurities to the substrate masked by the stack layer or the gate in the form of accelerated ions; and
annealing the source with a process temperature exceeding 650 degrees Celsius, such that the second conductive type impurities diffuse underneath the spacer layer relatively near the first side.
